(19) United States
(12) Patent Application Publication
(10) Pub. No.: US 2008/0151135 A1
(43) Pub. Date: Jun. 26, 2008

(54) Common voltage adjustment apparatus

(75) Inventors: Hung-Ming Yang, Tainan County (TW); Kuo-Chan Huang, Tainan County (TW); Lin-Kai Bu, Tainan County (TW)

Correspondence Address: RABIN & Berdo, PC, 1101 14TH STREET, NW, SUITE 500, WASHINGTON, DC, 20005, US

(73) Assignee: HIMAX TECHNOLOGIES LIMITED, Tainan County (TW)

(21) Appl. No.: 11/905,564

(22) Filed: Oct. 2, 2007

(30) Foreign Application Priority Data
Dec. 25, 2006 (TW) 95148826

(51) Int. Cl. G02F 1/133; G11C 17/00

(52) U.S. Cl. 349/33; 365/94

(57) ABSTRACT

A common voltage adjustment apparatus for adjusting a common voltage of a liquid crystal display (LCD) panel includes a data-read-write circuit and an output circuit. The data-read-write circuit includes a one-time-programmable (OTP) memory module and a control interface unit. The OTP memory module includes several OTP memories. The control interface unit outputs common-voltage-setting data according to a control signal and selectively stores the common-voltage-setting data into an unwritten OTP memory in the OTP memory module. The output circuit includes a reference-voltage generator and a digital-to-analog converter (DAC). The reference-voltage generator generates a reference voltage. The DAC converts the common-voltage-setting data into an output voltage according to the reference voltage.

This application claims the benefit of Taiwan application Serial No. 95148826, filed Dec. 25, 2006, the subject matter of which is incorporated herein by reference.

### BACKGROUND OF THE INVENTION

1. Field of the Invention

The invention relates in general to a common voltage adjustment apparatus, and more particularly to a common voltage adjustment apparatus using OTP memories.

2. Description of the Related Art

When a liquid crystal display (LCD) panel is being manufactured, a common voltage of the panel has to be calibrated. An EEPROM (Electrically-Erasable Programmable Read-Only Memory) is usually used in the common voltage adjustment apparatus of the conventional LCD to store the adjusted common voltage. The EEPROM can be repeatedly erased and can record the adjusted common voltage for many times. However, the EEPROM cannot be manufactured according to the standard logic process, and additional processes have to be adopted to form the EEPROM in the conventional common voltage adjustment apparatus so that the manufacturing cost is too high.

### SUMMARY OF THE INVENTION

The invention is directed to a common voltage adjustment apparatus for adjusting a common voltage of a liquid crystal display (LCD) panel. A memory module having several one-time-programmable (OTP) memories is used to access adjusted common-voltage-setting data so that several adjusted common voltages can be repeatedly stored. Because the OTP memories can be manufactured according to the standard logic process, the common voltage adjustment apparatus of the invention can store the adjusted common voltages in the OTP memories without the need of any special manufacturing process. Thus, the manufacturing cost can be reduced, and the adjusted common voltage can be recorded for many times.

According to the present invention, a common voltage adjustment apparatus for adjusting a common voltage of a LCD panel is provided. The common voltage adjustment apparatus includes a data-read-write circuit and an output circuit. The data-read-write circuit includes a one-time-programmable (OTP) memory module and a control interface unit. The OTP memory module includes several OTP memories. The control interface unit outputs common-voltage-setting data according to a control signal and selectively stores the common-voltage-setting data into an unwritten OTP memory of the OTP memory module. The output circuit includes a reference-voltage generator and a digital-to-analog converter (DAC). The reference-voltage generator generates a reference voltage. The DAC converts the common-voltage-setting data into an output voltage according to the reference voltage.

The invention will become apparent from the following detailed description of the preferred but non-limiting embodiments. The following description is made with reference to the accompanying drawings.

### BRIEF DESCRIPTION OF THE DRAWINGS

FIG. 1 is a block diagram showing a common voltage adjustment apparatus according to an embodiment of the invention.

FIG. 2 is a block diagram showing another common voltage adjustment apparatus according to the embodiment of the invention.

FIG. 3 is a circuit diagram showing an output adjustment circuit in the common voltage adjustment apparatus of FIG. 2.

### DETAILED DESCRIPTION OF THE INVENTION

The common voltage adjustment apparatus according to the embodiment of the invention adjusts a common voltage of a liquid crystal display (LCD) panel, wherein a one-time-programmable (OTP) memory module is utilized to store common-voltage-setting data of the adjusted common voltage. The common voltage adjustment apparatus according to the embodiment of the invention further reads the latest written common-voltage-setting data from the OTP memory module, and accordingly generates the common voltage of the LCD panel.

FIG. 1 is a block diagram showing a common voltage adjustment apparatus 100 according to an embodiment of the invention. Referring to FIG. 1, the common voltage adjustment apparatus 100 includes a data-read-write circuit 110 and an output circuit 120. The data-read-write circuit 110 includes a control interface unit 111 and a one-time-programmable (OTP) memory module 113. The output circuit 120 includes a reference-voltage generator 121 and a digital-to-analog converter (DAC) 122. The OTP memory module 113 includes several OTP memories. In this embodiment, the OTP memory module 113 includes 32 OTP memories, and each OTP memory can store 8 bits of data.

The control interface unit 111 receives a control signal Ct and outputs common-voltage-setting data Dset, which corresponds to the control signal Ct, to the DAC 122. The reference-voltage generator 121 outputs a reference voltage Vref to the DAC 122. The DAC 122 converts the common-voltage-setting data Dset into an output voltage Vo in a digital-to-analog manner according to the reference voltage Vref and accordingly outputs the output voltage Vo. In this embodiment, the output voltage Vo serves as the common voltage of the LCD. Consequently, the common voltage adjustment apparatus according to the embodiment of the invention can adjust the common voltage of the LCD by adjusting the control signal Ct.

The control interface unit 111 can store the common-voltage-setting data Dset corresponding to the output voltage Vo into an unwritten OTP memory in the OTP memory module 113. The operations of writing the common-voltage-setting data Dset into the OTP memory module in the common voltage adjustment apparatus 100 according to the embodiment of the invention will be described in the following.

When the control interface unit 111 writes the common-voltage-setting data Dset into the OTP memory module, the control interface unit 111 first reads the OTP memories of the OTP memory module 113 sequentially. Because the OTP memory only can be written for one time, the unwritten OTP memory among the 32 OTP memories of the OTP memory module 113 has to be found first.

If the control interface unit 111 has read that the data stored in an N^{th} OTP memory, among the 32 OTP memories, equal to an initial value, and the data stored in the (N+1)^{th} OTP memory also equal to the initial value (i.e., the data stored in continuous two OTP memories equal to the initial values), it represents that the N^{th} OTP memory is the unwritten OTP memory. Thus, the control interface unit 111 can store the common-voltage-setting data Dset into the N^{th} OTP memory, wherein N is a positive integer smaller than 32.

The common voltage adjustment apparatus 100 according to the embodiment of the invention adjusts the output voltage Vo. According to the above-mentioned writing method of the OTP memory module, the common-voltage-setting data Dset corresponding to the adjusted output voltage Vo is written into the unwritten OTP memory of the OTP memory module. Thus, the common voltage adjustment apparatus 100 can store the common-voltage-setting data Dset corresponding to different output voltages Vo for many times.

In addition, the control interface unit 111 may also read the common-voltage-setting data Dset stored in the OTP memory module after the common voltage has been calibrated, and thus generates and provides the output voltage Vo for the LCD panel. When the common-voltage-setting data Dset is to be read, the control interface unit 111 sequentially reads the 32 OTP memories of the OTP memory module 113. If the control interface unit 111 has read that the data stored in the (K+1)^{th} OTP memory equal to the initial value and the data stored in the K^{th} OTP memory unequal to the initial value, the common-voltage-setting data Dset stored in the K^{th} OTP memory is outputted to the DAC 122, wherein K is a positive integer smaller than 32. The common-voltage-setting data Dset read by the control interface unit 111 is always the latest stored common-voltage-setting data Dset of the OTP memory module 113.

After receiving the common-voltage-setting data Dset, the DAC 122 converts the common-voltage-setting data Dset into the corresponding output voltage Vo according to the reference voltage Vref.

The reason why the data stored in the continuous two OTP memories must equal to the initial values when the common-voltage-setting data Dset is being written will be described in the following. Because the manufacturing process of the OTP memory may have problems, the data stored in the unwritten OTP memory may not equal to the initial value. Illustrations will be made according to an example, in which the N^{th} and (N+1)^{th} OTP memories among the 32 OTP memories are unwritten memories, the data stored in the N^{th} OTP memory equals to the initial value, and the data stored in the (N+1)^{th} OTP memory does not equal to the initial value. If the control interface unit 111 has read the N^{th} OTP memory, which equals to the initial value, the common-voltage-setting data Dset is written into the N^{th} OTP memory. Thereafter, when the control interface unit 111 sequentially reads the OTP memory, the data of the (N+1)^{th} OTP memory may be incorrectly read as the latest written common-voltage-setting data Dset. At this time, the latest written common-voltage-setting data Dset is stored in the N^{th} OTP memory. Thus, if the common-voltage-setting data Dset is to be written, the continuous two OTP memories both storing the initial values as the data have to be found to ensure that the common voltage adjustment apparatus 100 can subsequently read the latest written common-voltage-setting data Dset.

The control signal Ct may be a digital control signal. At this time, the control interface unit 111 may be designed as a digital control unit for outputting the corresponding common-voltage-setting data to the DAC 122 or accessing the OTP memory module according to the digital control signal.

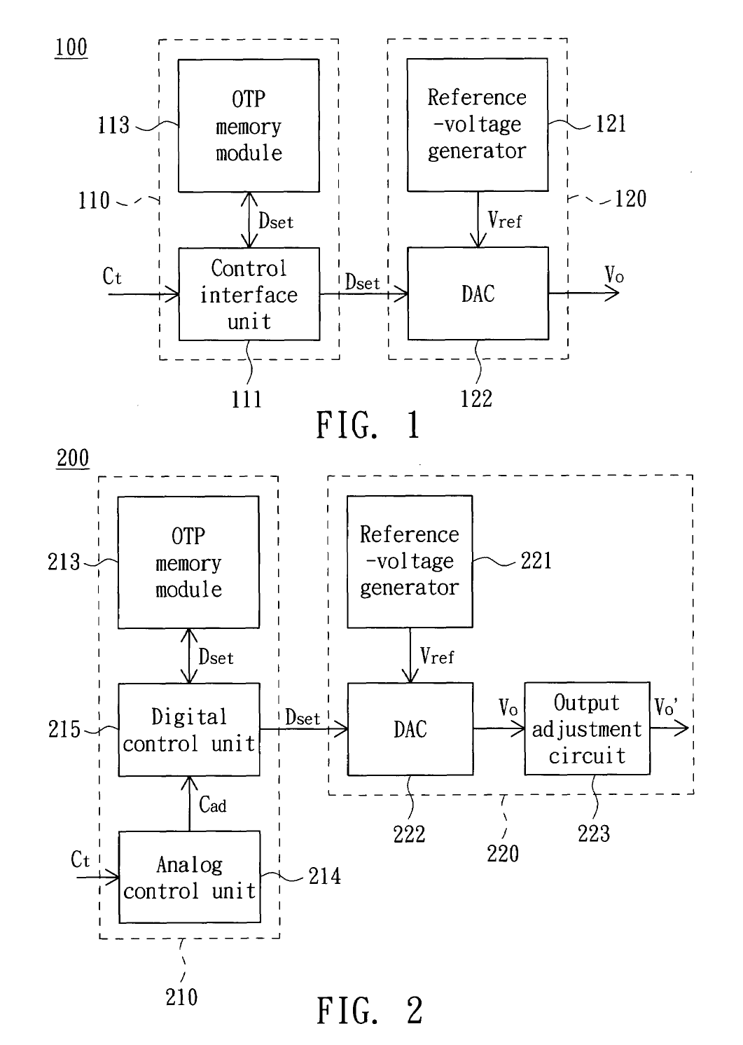

FIG. 2 is a block diagram showing another common voltage adjustment apparatus 200 according to the embodiment of the invention. Referring to FIG. 2, the common voltage adjustment apparatus 200 includes a data-read-write circuit 210 and an output circuit 220. What is different from the common voltage adjustment apparatus 100 of FIG. 1 is that the data-read-write circuit 210 further includes an analog control unit 214 and a digital control unit 215 and the control signal Ct is an analog control signal. The analog control unit 214 receives the control signal Ct and thus outputs a digital control signal Cad to the digital control unit 215. The digital control unit 215 outputs the common-voltage-setting data Dset corresponding to the digital control signal Cad to the DAC 222 so that the corresponding output voltage Vo is outputted.

The digital control unit 215 may also write the common-voltage-setting data Dset to the OTP memory module 213, or read the common-voltage-setting data Dset from the OTP memory module 213. The digital control signal Cad accesses the OTP memory module 213 in a manner the same as that for the control signal Ct to access the OTP memory module 113 in FIG. 1.

Referring to FIG. 2, the output circuit 220 may further include an output adjustment circuit 223. The output adjustment circuit receives the output voltage Vo, finely adjusts the output voltage Vo and then outputs an adjusted output voltage Vo′. The output adjustment circuit 223 may be a buffer circuit or a current sink circuit.

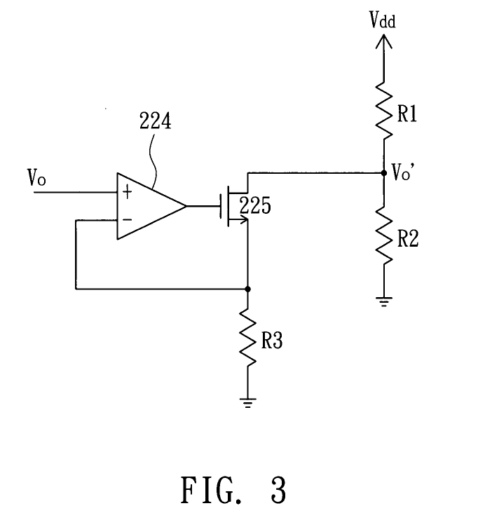

FIG. 3 is a circuit diagram showing the output adjustment circuit in the common voltage adjustment apparatus of FIG. 2. Referring to FIG. 3, the output adjustment circuit includes an OP amplifier 224, a transistor 225, a first resistor R1, a second resistor R2 and a third resistor R3. The output voltage Vo outputted from the DAC 222 is inputted to a positive input terminal of the OP amplifier 224. The output terminal of the OP amplifier 224 is coupled to the gate of the transistor 225. A negative input terminal of the OP amplifier 224 is coupled to the source of the transistor 225. The first resistor R1 is coupled between a positive voltage Vdd and the drain of the transistor 225. The second resistor R2 is connected between the drain of the transistor 225 and the ground. The third resistor R3 is connected between the source of the transistor 225 and the ground. The third resistor R3 controls the current flowing through the transistor 225. Thus, adjusting the resistance value of the third resistor R3 can finely adjust the output voltage Vo to obtain the adjusted output voltage Vo′.

In the above-mentioned embodiment, the OTP memory module includes, for example and without limitation to, the 32 OTP memories, and each of the OTP memories has the data storage of 8 bits.

The common voltage adjustment apparatus according to the embodiment of the invention adjusts the common voltage of the LCD panel and utilize the OTP memories to access the adjusted common-voltage-setting data. The OTP memory module has several OTP memories which can record the common-voltage-setting data with multiple adjusted common voltages. Because the OTP memory can be manufactured according to the standard logic process, the common voltage adjustment apparatus of the invention can have the reduced manufacturing cost and can record the adjusted common voltages for many times without the special manufacturing process being performed.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A common voltage adjustment apparatus for adjusting a common voltage of a liquid crystal display (LCD) panel, the common voltage adjustment apparatus receiving a control signal and thus outputting the common voltage of the LCD panel, the common voltage adjustment apparatus comprising:
a data-read-write circuit, which comprises:
a one-time-programmable (OTP) memory module comprising a plurality of OTP memories; and
a control interface unit for outputting a common-voltage-setting data according to the control signal and selectively storing the common-voltage-setting data into an unwritten OTP memory in the OTP memory module; and
an output circuit, which comprises:
a reference-voltage generator for generating a reference voltage; and
a digital-to-analog converter (DAC) for converting the common-voltage-setting data into an output voltage according to the reference voltage.

2. The apparatus according to claim 1, wherein the control interface unit further selectively reads the OTP memory module to obtain the common-voltage-setting data and outputs the common-voltage-setting data to the DAC.

3. The apparatus according to claim 1, wherein
the OTP memory module comprises M OTP memories;
wherein when the control interface unit writes the common-voltage-setting data into the OTP memory module, the control interface unit sequentially reads the OTP memories; the control interface unit stores the common-voltage-setting data into an N^{th} OTP memory when the control interface unit reads data of the N^{th} OTP memory and data of an (N+1)^{th} OTP memory all equal to an initial value;
wherein M is a positive integer greater than 1 and N is a positive integer smaller than M.

4. The apparatus according to claim 1, wherein:
the OTP memory module comprises M OTP memories;
wherein when the control interface unit reads the common-voltage-setting data, the control interface unit sequentially reads the OTP memories; the control interface unit outputs data of an N^{th} OTP memory as the common-voltage-setting data to the DAC when the control interface unit read a data of a N^{th} OTP memory unequal to an initial value and a data of a (N+1)^{th} OTP memory equal to the initial value;
wherein M is a positive integer greater than 1 and N is a positive integer smaller than M.

5. The apparatus according to claim 1, wherein the control signal is an analog control signal, the control interface unit comprises:
an analog control unit for receiving the analog control signal and accordingly outputting a digital control signal; and
a digital control unit for outputting the common-voltage-setting data to the DAC according to the digital control signal, and selectively storing the common-voltage-setting data into the unwritten OTP memory in the OTP memory module according to the digital control signal.

6. The apparatus according to claim 5, wherein the digital control unit further selectively reads the OTP memory module to obtain the common-voltage-setting data, and outputs the common-voltage-setting data to the DAC.

7. The apparatus according to claim 5, wherein the output circuit further comprises:
an output adjustment circuit for receiving the output voltage and outputting an adjusted output voltage.

8. The apparatus according to claim 1, wherein the control interface unit is a digital control unit and the control signal is a digital control signal.

9. The apparatus according to claim 1, wherein the OTP memory module comprises 32 OTP memories, and data storage size of each of the OTP memories is equal to 8 bits.

10. The apparatus according to claim 1, wherein the output circuit further comprises:
an output adjustment circuit for receiving the output voltage and outputting an adjusted output voltage.

11. The apparatus according to claim 10, wherein the output adjustment circuit is a buffer circuit.

12. The apparatus according to claim 10, wherein the output adjustment circuit is a current sink circuit.

13. The apparatus according to claim 12, wherein the output adjustment circuit comprises:
a transistor having a drain coupled to an output node having a voltage defined as the adjusted output voltage;
an OP amplifier having a positive input terminal for receiving the output voltage, a negative input terminal coupled to a source of the transistor, and an output terminal coupled to a gate of the transistor;
a first resistor connected between the output node and a positive voltage source;
a second resistor connected between the output node and a ground; and
a third resistor connected between the source of the transistor and the ground.
